(19) United States
(12) Patent Application Publication
(10) Pub. No.: US 2017/0299699 A1
(43) Pub. Date: Oct. 19, 2017

(54) PHOTO DETECTOR AND LIDAR DEVICE

(71) Applicant: KABUSHIKI KAISHA TOSHIBA, Tokyo (JP)

(72) Inventors: Toshiya YONEHARA, Kawasaki (JP); Kazuhiro SUZUKI, Tokyo (JP); Rei HASEGAWA, Yokohama (JP)

(73) Assignee: KABUSHIKI KAISHA TOSHIBA, Tokyo (JP)

(21) Appl. No.: 15/451,598

(22) Filed: Mar. 7, 2017

(30) Foreign Application Priority Data
Apr. 13, 2016 (JP) 2016-080115

(51) Int. Cl. G01S 7/481; H01L 31/0216; H01L 27/146; H01L 31/107; G01S 17/08

(52) U.S. Cl. CPC G01S 7/4816; H01L 31/107; G01S 17/08; H01L 27/14643; H01L 31/02161

(57) ABSTRACT

In one embodiment, a photo detector is provided with a semiconductor layer having a projection portion provided at a side opposite to a light receiving surface side, and a reflective material which covers a surface of the projection portion and reflects a light incident from the light receiving surface. In the photo detector, the projection portion layer has a slope portion, and an angle α of a slope surface of the slope portion to the light receiving surface satisfies

$$\frac{1}{2} arcsin \frac{1}{{n}_{1}} \leq α \leq \frac{1}{2} arctan \frac{L}{D}$$

using a refractive index n₁ of the projection portion of the semiconductor layer, a length D of the semiconductor layer in a direction from the light receiving surface toward the projection portion, and a length L of the projection portion in the horizontal direction.

### CROSS-REFERENCE TO RELATED APPLICATION

This application is based upon and claims the benefit of priority from the prior Japanese Patent Application No. 2016-080115, filed on Apr. 13, 2016, the entire contents of which are incorporated herein by reference.

### FIELD

Embodiments described herein relate generally to a photo detector and a LIDAR (Laser Imaging Detection and Ranging) device.

### BACKGROUND

A photo detector using an avalanche photo diode (APD) detects weak light, and amplifies a signal to be outputted. When an APD is made of silicon (Si), light sensitivity characteristic of the photo detector largely depends on absorption characteristic of silicon. The APD made of silicon most absorbs light with a wavelength of 400-600 nm. The APD hardly has sensitivity to light of a near infra-red wavelength band of not less than 750 nm. In order to improve the sensitivity of a photo detector using silicon, a device is known in which a depletion layer is made very thick, such as several ten μm, to have sensitivity to light of a near infra-red wavelength band. However, a drive voltage of the photo detector might become very high, such as several hundred volts.

Accordingly, in a photo detector using silicon, in order to enhance detection efficiency of light of wavelengths not less than 750 nm, a structure to confine light inside the photo detector has been considered.

### BRIEF DESCRIPTION OF THE DRAWINGS

FIG. 1A is a diagram showing a photo detector.

FIG. 1B is a diagram showing the photo detector seen in the xz plane.

FIG. 2 is a diagram showing the relation between a length of the optical path conversion portion and an incident angle of light.

FIG. 3 is a diagram showing an aspect that light is incident on the photo detector.

FIG. 4A is a diagram showing a photo detector.

FIG. 4B is a diagram showing the photo detector seen in the xz plane.

FIG. 5A is a diagram showing an aspect that light is incident on the photo detector.

FIG. 5B is a diagram showing the aspect that light is incident on the photo detector.

FIG. 6A is a diagram showing the relation between a length of the optical path conversion portion and a light absorption efficiency.

FIG. 6B is a diagram showing the relation between a length of the optical path conversion portion and a light absorption efficiency.

FIG. 7A is a diagram showing the relation between a length of the n type semiconductor layer and a light absorption efficiency of the photo detector.

FIG. 7B is a diagram showing the relation between a length of the n type semiconductor layer and a light absorption efficiency of the photo detector.

FIG. 7C is a diagram showing the relation between a length of the n type semiconductor layer and a light absorption efficiency of the photo detector.

FIG. 7D is a diagram showing the relation between a length of the n type semiconductor layer and a light absorption efficiency of the photo detector.

FIG. 8 is a diagram showing the relation between an internal transmissivity of the photo detector and a light absorption efficiency thereof.

FIG. 9 is a diagram showing a photo detector.

FIG. 10 is a diagram showing the relation between a length of the optical path conversion portion and a light absorption efficiency.

FIG. 11A is a diagram showing the relation between a length of the optical path conversion portion and a light absorption efficiency.

FIG. 11B is a diagram showing the relation between a length of the optical path conversion portion and a light absorption efficiency.

FIG. 12 is a diagram showing a photo detector.

FIG. 13A is a diagram showing the relation between a light absorption efficiency and a length of the optical path conversion portion.

FIG. 13B is a diagram showing the relation between a light absorption efficiency and a wavelength of light.

FIG. 14A is a diagram showing a photo detector.

FIG. 14B is a diagram showing a photo detector.

FIG. 15 is a diagram showing a photo detector.

FIG. 16 is a diagram showing the relation between a length of the optical path conversion portion and a light absorption efficiency.

FIG. 17A is a diagram showing a photo detector.

FIG. 17B is a diagram showing the photo detector seen in the xz plane.

FIG. 18A is a diagram showing the relation between a length of the optical path conversion portion and a light absorption efficiency.

FIG. 18B is a diagram showing a photo detector.

FIG. 19A is a diagram of a photo detector seen in an xz plane.

FIG. 19B is a circuit diagram of the photo detector.

FIG. 20A is a diagram of a photo detector seen in an xz plane.

FIG. 20B is a circuit diagram of the photo detector.

FIG. 21 is a diagram showing a manufacturing method of a photo detector.

FIG. 22A is a diagram showing a manufacturing method of a photo detector.

FIG. 22B is a diagram showing the manufacturing method of a photo detector.

FIG. 22C is a diagram showing the manufacturing method of a photo detector.

FIG. 23 is a configuration diagram of a LIDAR device.

FIG. 24 is a configuration diagram of a measuring system.

### DETAILED DESCRIPTION

According to one embodiment, a photo detector is provided with a semiconductor layer having a projection portion provided at a side opposite to a light receiving surface side, and a reflective material which covers a surface of the projection portion and reflects a light incident from the light receiving surface. In the photo detector, the projection portion has a slope portion, and an angle α of a slope surface of the slope portion to the light receiving surface satisfies

$$\frac{1}{2} arcsin \frac{1}{{n}_{1}} \leq α \leq \frac{1}{2} arctan \frac{L}{D}$$

using a refractive index n₁ of the projection portion of the semiconductor layer, a length D of the semiconductor layer in a direction from the light receiving surface toward the projection portion, and a length L of the projection portion in the horizontal direction.

Hereinafter, further embodiments of the present invention will be described with reference to the drawings. Ones with the same symbols show the similar ones. In addition, the drawings are schematic or conceptual, and accordingly, the relation between a thickness and a width in each portion, and a ratio coefficient of sizes between portions are not necessarily identical to those of the actual ones. In addition, even when the same portions are shown, the dimensions and the ratio coefficients thereof may be shown different depending on the drawings.

### First Embodiment

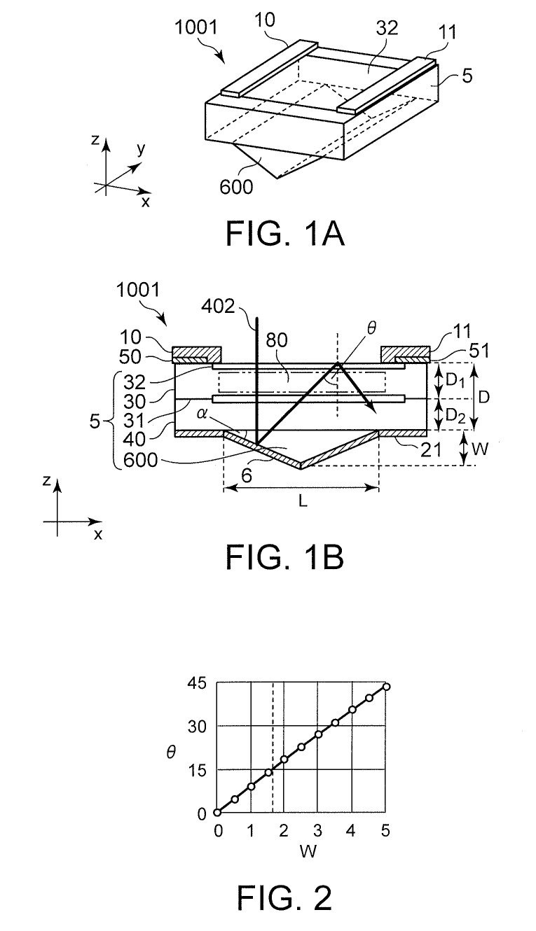

FIG. 1A is a diagram showing a photo detector 1001, and FIG. 1B is a sectional view showing the photo detector 1001 seen from an xz plane.

In FIG. 1A, the photo detector 1001 is composed of a p⁺ type semiconductor layer 32 serving as a light receiving surface for receiving light, first electrodes 10, 11, a semiconductor layer 5, and an optical path conversion portion 600.

In FIG. 1B, the photo detector 1001 is provided with the first electrodes 10, 11, insulating layers 50, 51, the p⁺ type semiconductor layer 32, a p⁻ type semiconductor layer 30, a p⁺ type semiconductor layer 31, an n type semiconductor layer 40, the optical path conversion portion (projection portion) 600, and a reflective material 21. The p⁺ type semiconductor layer 32, the p⁻ type semiconductor layer 30, the p⁺ type semiconductor layer 31, and the n type semiconductor layer 40 are collectively called a semiconductor layer 5.

The photo detector 1001 has a laminated structure in which the p⁻ type semiconductor layer 30 and the n type semiconductor layer 40 have been pn junction. The p⁺ type semiconductor layer 31 is provided between the p⁻ type semiconductor layer 30 and the n type semiconductor layer 40. The p⁺ type semiconductor layer 32 is provided on the p⁻ type semiconductor layer 30 at a side opposite to the n type semiconductor layer 40. The p⁺ type semiconductor layer 32 serves as a light receiving surface for receiving light. The light receiving surface has a quadrangular shape, and a length of a side thereof is not less than 20 μm and not more than 30 μm.

There is a region 80 in which a depletion layer serving as the photoelectric conversion portion is to be formed inside the p⁻ type semiconductor layer 30.

The first electrodes 10, 11 are provided above the p⁻ type semiconductor layer 30 at the same side as the p⁺ type semiconductor layer 32. The first electrodes 10, 11 are in contact with the p⁺ type semiconductor layer 32. The insulating layers 50, 51 are respectively provided between the first electrodes 10, 11 and the p⁻ type semiconductor layer 30.

The optical path conversion portion 600 is provided on the semiconductor layer 5 at a side opposite to the light receiving surface side. The optical path conversion portion (projection portion) 600 is contained in the semiconductor layer 5. In addition, the optical path conversion portion (projection portion) 600 is not a part of the semiconductor layer 5, but may be a portion separate from the semiconductor layer 5.

A surface of the optical path conversion portion 600 is covered with the material 21. The reflective material 21 is composed of metal such as Al (aluminum), Ag (silver), Au (gold), Cu (copper), or an alloy containing at least one of them, for example. Here, the reflective material 21 functions as an electrode as well. The reflective material 21 and the electrode may be separately composed from each other. An electric conductivity of the reflective material 21 is higher than an electric conductivity of the optical path conversion portion 600.

The optical path conversion portion 600 is formed of an n type semiconductor which is the same as the n type semiconductor layer 40, for example. It is preferable that a refractive index of the optical path conversion portion 600 is the same as a refractive index of the semiconductor layer 5. The optical path conversion portion 600 projects in a direction opposite to a direction to the p⁺ type semiconductor layer 32. The optical path conversion portion 600 is a triangle pole having a bottom surface in a y direction in FIG. 1A.

The semiconductor layer 5 is composed of a p⁻ type semiconductor layer and an n type semiconductor layer in this order, in the direction from the light receiving surface toward the projection portion

The semiconductor layer 5 is composed of the p⁺ type semiconductor layer 32, the p⁻ type semiconductor layer 30, the p⁺ type semiconductor layer 31, the n type semiconductor layer 40 in this order. The semiconductor layer 5 may not be provided with the p⁺ type semiconductor layers 31, 32, and may be a laminated structure of a p⁻ type semiconductor layer and an n type semiconductor layer. The semiconductor layer 5 may be composed of an n type semiconductor layer and a p⁻ type semiconductor layer in this order.

The semiconductor layer 5 may be composed of an n⁺ type semiconductor layer 32, an n⁻ type semiconductor layer, an n⁺ type semiconductor layer 31, a p⁻ type semiconductor layer in this order.

The semiconductor layer is composed of Si (silicon).

Hereinafter, a case containing the p⁺ type semiconductor layers 31, 32 will be described.

Light incident on the p⁺ type semiconductor layer 32 that is the light receiving surface will be described.

It is supposed that a wavelength of light incident on the p⁺ type semiconductor layer 32 that is the light receiving surface is not less than 750 nm and not more than 1000 nm.

A light 402 incident on the p⁺ type semiconductor layer 32 vertically from the outside is reflected by the reflective material 21 of the optical path conversion portion 600. The light 402 reflected by the reflective material 21 reaches an interface of the outside and the p⁺ type semiconductor layer 32.

A case in which the light 402 reflected by the reflective material 21 is incident on the interface of the outside and the p⁺ type semiconductor layer 32. When an incident angle θ of the light 402 is larger than a critical angle θ_{c} that is determined by a refractive index of the outside and a refractive index of the p⁺ type semiconductor layer 32, the light 402 are totally reflected by the interface of the outside and the p⁺ type semiconductor layer 32. Since the light 402 is totally reflected and stays inside the photo detector 1001, it is possible to confine the light 402 inside the photo detector 1001. Accordingly, it is possible to improve a detection efficiency of light of the photo detector 1001.

A length (depth) of the semiconductor layer 5 in a direction from the p⁺ type semiconductor layer 32 serving as the light receiving surface toward the optical path conversion portion 600 is decided as D. At this time, a length of the p⁻ type semiconductor layer 30 is decided as D₁, and a length of the n type semiconductor layer 40 is decided as D₂. The length D of the semiconductor layer 5 is a sum of the length D₁ of the p⁻ type semiconductor layer 30 and the length D₂ of the n type semiconductor layer 40.

The length D of the semiconductor layer 5 is not less than 1 μm and not more than 10 μm.

A length from the photoelectric conversion portion 5 to the most projecting portion of the optical path conversion portion 600, in the direction from the p⁺ type semiconductor layer 32 serving as the light receiving surface toward the optical path conversion portion 600 is decided as W. A length (width) of the optical path conversion portion 600 in the horizontal direction is decided as L.

The above-described optical path conversion portion 600 has a slope portion 6. An angle of a slope surface of the slope portion to the p⁺ type semiconductor layer 32 serving as the light receiving surface is decided as a.

FIG. 2 is a diagram showing change in the incident angle θ of light to the length W of the optical path conversion portion 600.

In this simulation, the length L of the optical path conversion portion 600 was decided as 25 μm. A refractive index n₁ of Si (silicon) in the light with a wavelength of 900 nm is 3.63. A refractive index n₂ of the outside is 1.0 of air.

The horizontal axis is decided as the length W of the optical path conversion portion 600, and the vertical axis is decided as the incident angle θ of light.

Based on the refractive index n₁ (=3.63) of the p⁺ type semiconductor layer 32 and the refractive index n₂ (=1.0) of the outside, the critical angle θ_{c} of the incident angle θ becomes about 16 degrees. The length W of the optical path conversion portion 600 at this time becomes about 1.79 μm from FIG. 2. Accordingly, the length W of the optical path conversion portion 600 has only to be not less than 1.79 μm, in order to confine the light in the photo detector 1001.

In order to confine the light inside the photo detector 1001, the angle α of the slope surface of the slope portion 6 of the optical path conversion portion 600 to the light receiving surface has only to satisfy an expression (1), based on the refractive index n₁ of the optical path conversion portion 600, the length W of the optical path conversion portion 600, and the length L of the optical path conversion portion 600 in the horizontal direction.

$$\frac{1}{2} arcsin \frac{1}{{n}_{1}} \leq α \leq \frac{1}{2} arctan \frac{L}{D} \qquad ( 1 )$$

The angle α of the slope surface of the slope portion 6 of the optical path conversion portion 600 to the light receiving surface is expressed as an expression (2).

$$α = arctan \frac{2 W}{L} \qquad ( 2 )$$

A range of the angle α is determined by the expression (1). Or, the range of the angle α may be a range determined by an expression (3). In this case, a lower limit value of the angle α is determined by a first expression of the expression (3). On the other hand, an upper limit value of the angle α is determined by substituting W to be determined by a second expression of the expression (3) into the expression (2). At this time, k is an extinction coefficient of the n type semiconductor composing the optical path conversion portion 600.

$$\frac{1}{2} arcsin \frac{1}{{n}_{1}} \leq α , 2 W \leq - \frac{λ ln 0.5}{4 π k} \qquad ( 3 )$$

In addition, the critical angle θ_{c} is expressed as an expression (4).

$${θ}_{C} = arcsin \frac{1}{{n}_{1}} \qquad ( 4 )$$

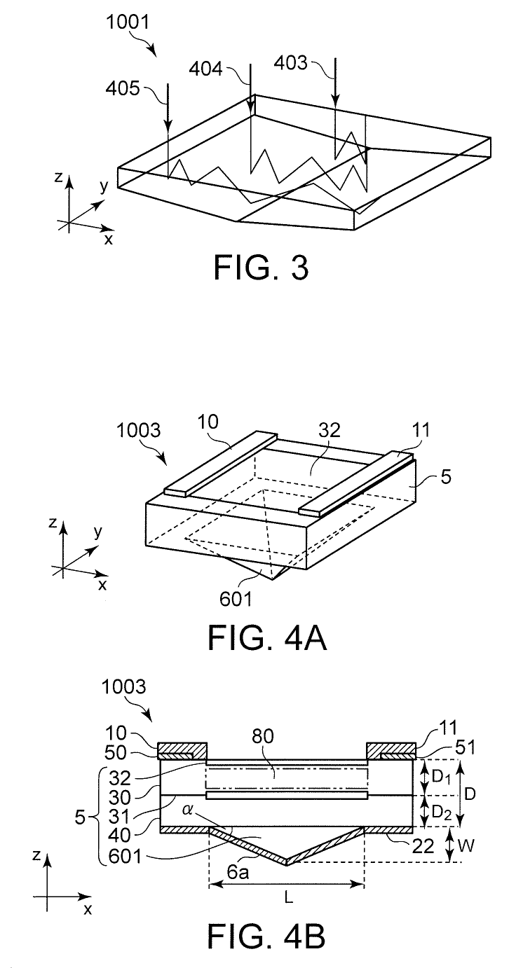

FIG. 3 is a diagram schematically showing the photo detector 1001, and showing aspects of a light 403, a light 404, and a light 405 which have been incident on the photo detector 1001.

After the light 403, the light 404, and the light 405 have been incident on the photo detector 1001, they are reflected by the optical path conversion portion 600. Further, the light 403, the light 404, and the light 405 are totally reflected by the interface of the outside and the p⁺ type semiconductor layer 32 serving as the light receiving surface for at least one or more times. Accordingly, the light 403, the light 404, and the light 405 are confined inside the photo detector 1001. When the light 403 and the light 405 are compared, the light 405 which has been incident on the position of the light 405 repeats the total reflection for more times than the light 403. When the light is reflected by the slope portion 6 having the same slop angle of the optical path conversion portion 600 for a plurality of times, the light is easily confined inside the photo detector 1001. If the light is totally reflected and is confined inside the photo detector 1001, the light passes through the depletion layer for many times, and accordingly, the detection efficiency of the photo detector 1001 is improved.

In addition, here, FIG. 3 has been calculated by simulation, in consideration of the light in which the incident angle θ of light has become larger than the critical angle θ_{c}. The photo detector 1001 is composed of Si (silicon). A refractive index of Si (silicon) in the light with a wavelength of 900 nm is 3.63. The length W of the optical path conversion portion 600 was decided as 2.0 μm, the length L of the optical path conversion portion 600 in the horizontal direction was decided as 25 μm, and the length D of the optical path conversion portion 600 in the direction from the p⁺ type semiconductor layer 32 serving as the light receiving surface toward the optical path conversion portion 600 was decided as 3.0 μm.

In addition, in the simulations of the respective lights, when the incident angle θ became smaller than the critical angle θ_{c}, or when light was not reflected by the interface of the outside and the p⁺ type semiconductor layer 32, the calculation was finished, assuming that the light had not been confined inside the photo detector 1001. In addition, when the internal transmissivity of the photo detector 1001 reached 10%, the calculation was finished assuming that the light had become extremely weak.

### Second Embodiment

FIG. 4A is a diagram showing a photo detector 1003, and FIG. 4B is a sectional view showing the photo detector 1003 seen from an xz plane.

The same symbols are given to the same portions of the photo detector 1003 as the photo detector 1001, and the description thereof will be omitted.

In the photo detector 1003 of FIG. 4A, an optical path conversion portion (projection portion) 601 is contained in the semiconductor layer 5. The optical path conversion portion 601 has a quadrangular pyramid shape having a bottom surface in an xy plane. The optical path conversion portion 601 is formed by the same material as the n type semiconductor layer 40. The optical path conversion portion 601 has the same refractive index as the semiconductor layer 5. In addition, the optical path conversion portion (projection portion) 601 is not a part of the semiconductor layer 5, but may be a portion separate from the semiconductor layer 5.

In FIG. 4B, the optical path conversion portion 601 has a slope portion 6a.

The region 80 in which a depletion layer serving as the photoelectric conversion portion is to be formed exists inside the p type semiconductor layer 30.

In a direction from the p⁺ type semiconductor layer 32 serving as the light receiving portion toward the optical path conversion portion 601, a length of the p⁻ type semiconductor layer 30 is decided as D₁, a length of the n type semiconductor layer 40 is decided as D₂, a length of the optical path conversion portion 601 is decided as W. A sum of the length D₁ of the p⁻ type semiconductor layer 30 and the length D₂ of the n type semiconductor layer 40 is decided as D. A length of the optical path conversion portion 601 in the horizontal direction is decided as L.

The angle α of the slope surface of the slope portion 6a of the optical path conversion portion 601 to the light receiving surface satisfies the expression (1) or the expression (3). In addition, the angle α is expressed by the expression (2) described above.

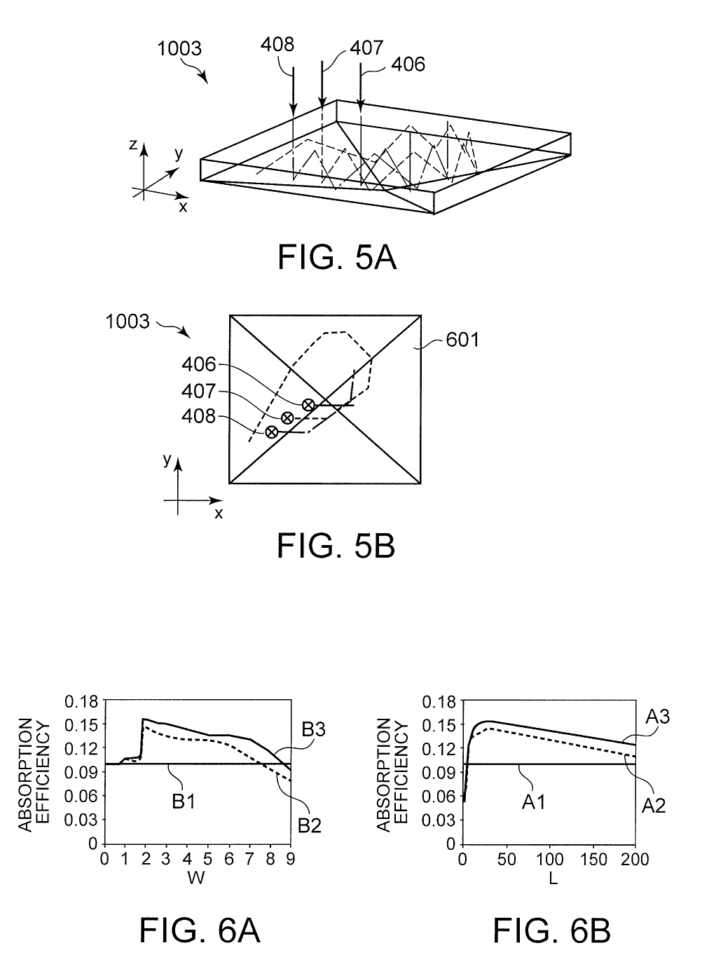

FIG. 5A is a diagram showing an aspect in which a light 406, a light 407, a light 408 are incident on the photo detector 1003, and FIG. 5B is a diagram showing the photo detector 1003 seen in an xy plane.

In FIG. 5A, the light 406, the light 407, and the light 408 are incident on the p⁺ type semiconductor layer 32 serving as the light receiving surface, and repeat total reflection inside the photo detector 1003. In addition, calculation was performed by simulation in the same condition as FIG. 3.

As shown in FIG. 5B, each of the light 406, the light 407, and the light 408 repeats total reflection inside the photo detector 1003 so as to draw a circle on the optical path conversion portion 601. Each of the light 406, the light 407, and the light 408 repeats total reflection, and thereby each of the light 406, the light 407, and the light 408 is confined inside the photo detector 1003.

FIG. 6A is a diagram showing the relation between the length W of each of the optical path conversion portions 600, 601 and an absorption efficiency of light absorbed in the region 80, and FIG. 6B is a diagram showing the relation between the length L of each of the optical path conversion portions 600, 601 and an absorption efficiency of light absorbed in the region 80.

In FIG. 6A, B1 indicates a light absorption efficiency of the photo detector 1001 which is not provided with the optical path conversion portion 600, or a light absorption efficiency of the photo detector 1003 which is not provided with the optical path conversion portion 601. B2 indicates a light absorption efficiency of the photo detector 1001. B3 indicates a light absorption efficiency of the photo detector 1003.

When the lengths W of the optical path conversion portions 600, 601 are 1.75-1.8 μm, the absorption efficiencies of light of B2 and B3 respectively rise. This is the condition in which the total reflection occurs as shown in FIG. 2.

When the length W of each of the optical path conversion portions 600, 601 is not more than at least 1.7 μm, large difference in the light absorption efficiency of each of the photo detectors 1001, 1003 is not generated without depending on the existence of the optical path conversion portions 600, 601.

When the lengths W of the optical path conversion portions 600, 601 are not less than at least 1.8 μm, the optical path conversion portions 600, 601 are respectively provided, and thereby the absorption efficiencies of the photo detectors 1001, 1003 increase. The photo detector 1003 has the larger effect to confine the light in the in-plane direction of the xy plane and has the higher light absorption efficiency than the photo detector 1001.

In addition, B1, B2 and B3 were calculated, assuming that the length D₁ of the p⁻ type semiconductor layer 30 is 3.0 μm, the length D₂ of the n type semiconductor layer 40 is 3.0 μm, in a direction from the light receiving surface toward each of the optical path conversion portions 600, 601. B1, B2 and B3 were calculated, assuming that the length L of each of the optical path conversion portions 600, 601 in the horizontal direction is 25 μm, and a refractive index of silicon (Si) in the light with a wavelength of 900 nm is 3.63.

In FIG. 6B, A1 indicates a light absorption efficiency of the photo detector 1001 which is not provided with the optical path conversion portion 600, or the photo detector 1003 which is not provided with the optical path conversion portion 601. A2 indicates a light absorption efficiency of the photo detector 1001. A3 indicates a light absorption efficiency of the photo detector 1003.

In addition, A1, A2 and A3 were calculated, assuming that the length D₁ of the p⁻ type semiconductor layer 30 is 3.0 μm, the length D₂ of the n type semiconductor layer 40 is 3.0 μm, in the direction from the light receiving surface toward each of the optical path conversion portions 600, 601. A1, A2 and A3 were calculated by changing the lengths L of the optical path conversion portions 600, 601 in the horizontal direction, respectively. W/L is decided as 0.08, and the angle α of each of the photo detectors 1001, 1003 is made constant. A refractive index of silicon (Si) in the light with a wavelength of 900 nm is 3.63.

When at least the lengths L of the optical path conversion portion 600, 601 are not more than 200 μm, the absorption efficiencies of light of A2 and A3 increase, respectively. In particular, when the lengths L of the optical path conversion portions 600, 601 are 20-30 μm, the absorption efficiencies of light of A2 and A3 become maximum, respectively.

If the lengths L of the optical path conversion portions 600, 601 are small, the lights reflected by the interfaces of the optical path conversion portions 600, 601 and the reflective materials 22 go out from the regions 80 in the in-plane direction, and thereby the absorption efficiencies of light of A2 and A3 decrease, respectively. If the lengths L of the optical path conversion portions 600, 601 are large, the lengths W of the optical path conversion portions 600, 601 become large, and thereby absorptions of light at regions outside the regions 80 increase, respectively. Accordingly, the absorption efficiencies of light of A2 and A3 decrease.

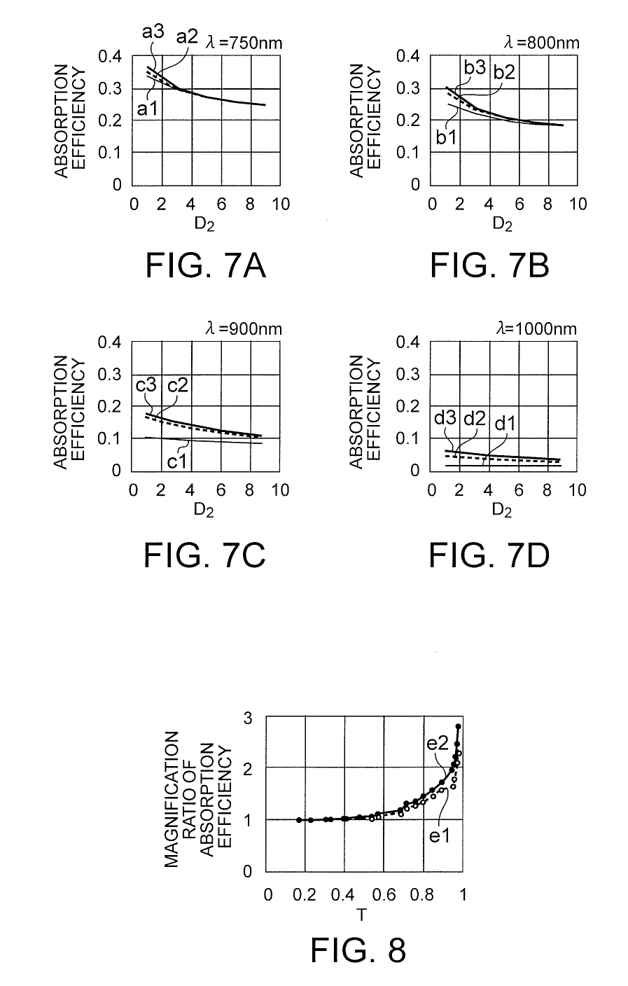

FIGS. 7A to 7D are diagrams, each showing the relation between the length D₂ of the n type semiconductor layer 40 of each of the photo detector 1001 and the photo detector 1003 and a light absorption efficiency thereof which has been absorbed in the region 80.

FIG. 7A shows an absorption efficiency of light with a wavelength of 750 nm, FIG. 7B shows an absorption efficiency of light with a wavelength of 800 nm, FIG. 7C shows an absorption efficiency of light with a wavelength of 900 nm, and FIG. 7D is a diagram showing an absorption efficiency of light with a wavelength of 1000 nm.

In FIG. 7A to FIG. 7D, each of a1, b1, c1, and d1 indicates a light absorption efficiency of the photo detector 1001 which is not provided with the optical path conversion portion 600, or the photo detector 1003 which is not provided with the optical path conversion portion 601. Each of a2, b2, c2, and d2 indicates a light absorption efficiency of the photo detector 1001. Each of a3, b3, c3, and d3 indicates a light absorption efficiency of the photo detector 1003.

In any cases of lights with wavelengths of 750 nm, 800 nm, 900 nm, and 1000 nm, it was found that the smaller the length D₂ of the n type semiconductor layer 40 is, the more the light absorption efficiency in the region 80 increases. That is, when a thickness of the semiconductor layer 5 becomes small, a light absorption efficiency in the region 80 is improved. In particular, when a wavelength of light is long, and each of the optical path conversion portions 600, 601 is provided, the effect of absorbing light in the region 80 is large.

In addition, the light absorption efficiency of the photo detector 1001 and the light absorption efficiency of the photo detector 1003 were calculated assuming that the length D₁ of the p⁻ type semiconductor layer 30 is 3.0 μm, the length W of each of the optical path conversion portions 600, 601 is 2.0 μm, and the width L of each of the optical path conversion portions 600, 601 is 25 μm.

FIG. 8 is a diagram showing the relation between a magnification ratio of a light absorption efficiency and an internal transmissivity T in each of the photo detectors 1001, 1003, to each of a case of the photo detectors 1001, 1003 without the optical path conversion portions 600, 601

The horizontal axis shows an internal transmissivity T, and the vertical axis shows a magnification ratio of the light absorption efficiency.

e1 indicates a magnification ratio of a light absorption efficiency of the photo detector 1001, to a case of the photo detector 1001 without the optical path conversion portion 600. e2 indicates a magnification ratio of a light absorption efficiency of the photo detector 1003, to a case of the photo detector 1003 without the optical path conversion portion 601.

In this calculation result, the internal transmissivities T expressed by an expression (5) were calculated for the whole results obtained in FIG. 7A to FIG. 7D. The internal transmissivities T indicate light intensities when lights have reached the optical path conversion portions 600, 601, based on light intensities of lights incident on the photo detectors 1001, 1003, respectively.

$$T = exp ( - \frac{4 π}{λ} k ( {D}_{1} + {D}_{2} ) ) \qquad ( 5 )$$

If the internal transmissivity T is not less than at least 0.5, the magnification ratio of the light absorption efficiency rises in each of the optical path conversion portion 600 of the photo detector 1001 and the optical path conversion portion 601 of the photo detector 1003. When lights incident on the photo detectors 1001, 1003 have reached the optical path conversion portions 600, 601, in a case in which the lights of not less than 50% remain without being absorbed, it is possible to improve the absorption efficiencies of light by the optical path conversion portions 600, 601, respectively.

### Third Embodiment

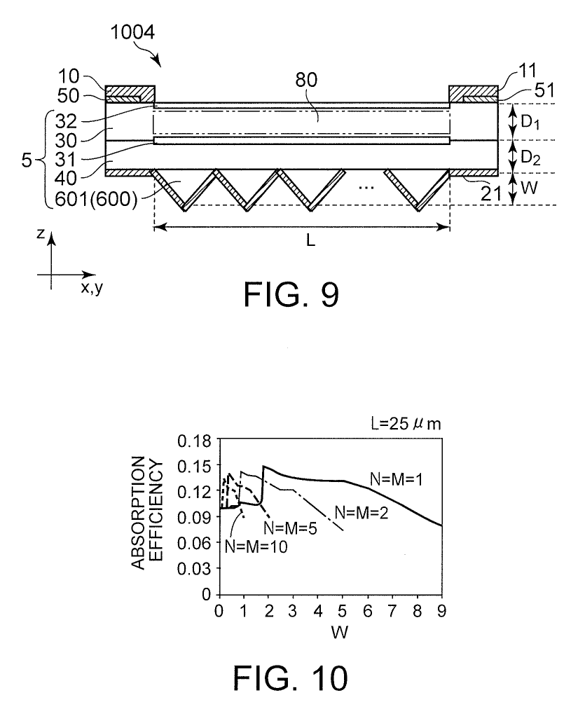

FIG. 9 is a diagram showing a photo detector 1004.

The same symbols are given to the same portions as the FIGS. 1A, 1B and FIGS. 4A, 4B, and the description thereof will be omitted. In the photo detector 1004, a plurality of the optical path conversion portions 600 of the photo detector 1001 or a plurality of the optical path conversion portions 601 of the photo detector 1003 are arranged. The photo detector 1004 is provided with a plurality of the optical path conversion portions 600 or 601 for the one p⁺ type semiconductor layer 32. The optical path conversion portions 600 or 601 are arranged by N (≧1) pieces in an x axis direction and by M (≧1) pieces in a y axis direction. A length of the plurality of optical path conversion portions 600 or 601 in the horizontal direction is decided as L.

FIG. 10 is a diagram showing the relations between the length W of the optical path conversion portion 600 or 601 and a light absorption efficiency in the region 80, when N=M=1, 2, 5, 10, respectively.

From FIG. 10, it is found that the smaller the number N of the optical path conversion portions 600 or 601 arranged in the x axis direction and the number M of the optical path conversion portions 600 or 601 arranged in the y axis direction are respectively, the more the light absorption efficiency in the region 80 increases in a large range of the length W of the optical path conversion portions 600 or 601. The more the number N of the optical path conversion portions 600 or 601 arranged in the x axis direction and the number M of the optical path conversion portions 600 or 601 arranged in the y axis direction are respectively, the more a maximum value of the light absorption efficiency in the region 80 increases.

In addition, the light absorption efficiency in the region 80 is calculated assuming that the length L of the plurality the arranged optical path conversion portions 600 or 601 is 25 μm, the length D₁ of the p⁻ type semiconductor layer 30 is 3.0 μm, and the length D₂ of the n type semiconductor layer 40 is 3.0 μm.

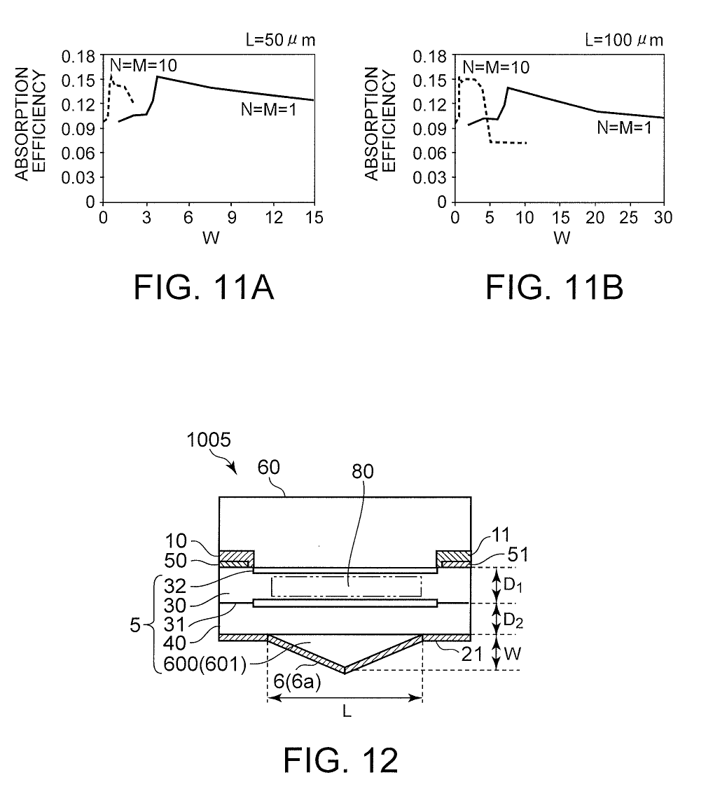

FIGS. 11A and 11B are diagrams each showing the relations between the length W of the optical path conversion portions 600 or 601 and a light absorption efficiency in the region 80, when N=M=1, 2, respectively.

FIG. 11A shows a case in which the length L of the plurality of arranged optical path conversion portions 600 or 601 is 50 μm, and FIG. 11B shows a case in which the length L of the plurality of arranged optical path conversion portions 600 or 601 is 100 μm.

In any of a case in which the length L of the plurality of arranged optical path conversion portions 600 or 601 is 50 μm, and a case in which the length L of the plurality of arranged optical path conversion portions 600 or 601 is 100 μm, the smaller the number N of the optical path conversion portions 600 or 601 arranged in the x axis direction and the number M of the optical path conversion portions 600 or 601 arranged in the y axis direction are respectively, the more the light absorption efficiency in the region 80 increases in a large range of the length W of the optical path conversion portions 600 or 601.

From the absorption efficiencies of light in the region 80 in respective cases in which the lengths L of the optical path conversion portions 600 or 601 are 25 μm, 50 μm, 100 μm, it is found that the light absorption efficiency becomes a maximum value when the length L of the optical path conversion portions 600 or 601 is 25 μm.

In addition, the light absorption efficiency in the region 80 is calculated assuming that the length D₁ of the p⁻ type semiconductor layer 30 is 3.0 μm, and the length D₂ of the n type semiconductor layer 40 is 3.0 μm.

In addition, the photo detector 1004 may be provided with not only the optical path conversion portion 600 or the optical path conversion portion 601, but also one of optical path conversion portions 602, 603, 605 described later.

### Fourth Embodiment

FIG. 12 is a diagram showing a photo detector 1005 which is further provided with a substrate 60 on the p⁺ type semiconductor layer 32.

The same symbols are given to the same portions as the FIGS. 1A, 1B and FIGS. 4A, 4B, and the description thereof will be omitted.

The photo detector 1005 is further provided with the substrate 60 on the p⁺ type semiconductor layer 32 of the photo detector 1001 or 1003.

The substrate 60 is adhered to the p⁺ type semiconductor layer 32 by an adhesive layer, for example.

The substrate 60 is composed of a light transmitting material. The substrate 60 is glass, for example.

Light is detected by a depletion layer formed in the region 80 of the photo detector 1005.

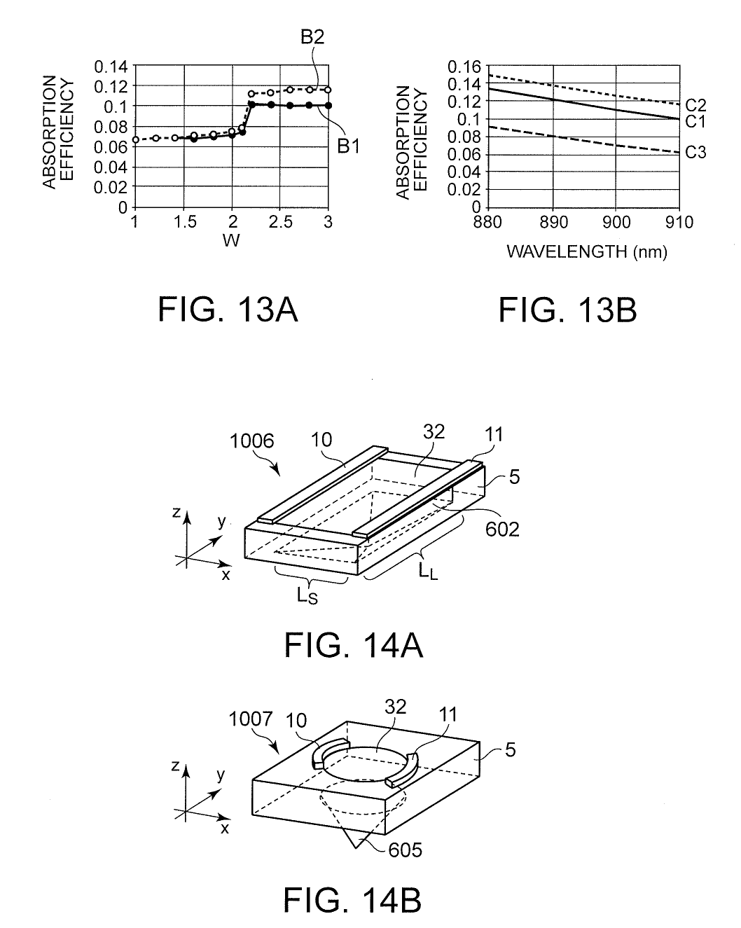

FIG. 13A is a diagram showing the relation between a light absorption efficiency in the region 80 of the photo detector 1005 and a length W of the optical path conversion portion 600 (601), and FIG. 13B is a diagram showing the relation between a light absorption efficiency in the region 80 of the photo detector 1005 and a wavelength of light.

In FIG. 13A, B1 is a light absorption efficiency in the region 80 of the photo detector 1005 which is provided with the optical path conversion portion 600. B2 is a light absorption efficiency in the region 80 of the photo detector 1005 which is provided with the optical path conversion portion 601.

From B1 and B2, it is found that when the length W of the optical path conversion portion 600 or 601 exceeds at least 2.2 μm, the light absorption efficiency in the region 80 rises. In the case in which the substrate 60 exists, the angle α has only to satisfy an expression (6).

$$\frac{1}{2} arcsin \frac{{n}_{2}}{{n}_{1}} \leq α \leq \frac{1}{2} arctan \frac{L}{D} \qquad ( 6 )$$

A range of the angle α is determined by the expression (6). Or the range of the angle α may be a range determined by an expression (7). In this case, a lower limit value of the angle α is determined by a first expression in the expression (7). On the other hand, an upper limit value of the angle α is determined by substituting W to be determined by the second expression of the expression (7) in the expression (2). At this time, k is an extinction coefficient of the n type semiconductor composing the optical path conversion portion 600.

$$\frac{1}{2} arcsin \frac{{n}_{2}}{{n}_{1}} \leq α , 2 W \leq - \frac{λ ln 0.5}{4 π k} \qquad ( 7 )$$

The length L of the optical path conversion portion 600 or 601 is 20 μm. n₂ is a refractive index of the substrate 60. The refractive index n₂ of the substrate 60 in light with a wavelength of 905 nm is about 1.514. A refractive index of the optical path conversion portion 600 or 601 is decided as n₁. When the semiconductor is Si (silicon), the refractive index n₁ in light with a wavelength of 905 nm is about 3.627. At this time, the length W of the optical path conversion portion 600 or 601 is calculated to be larger than 2.19 μm from the expression (6).

In addition, the length D₁ of the p⁻ type semiconductor layer 30 was decided as 3.0 μm, and a sum of the length D₂ of the n type semiconductor layer 40 and the length W of the optical path conversion portion 600 (601) was decided as 5.0 μm. In a direction from the light receiving surface to the optical path conversion portion 600 (601), a length of the substrate 60 was decided as 300 μm, and a length of the region 80 was decided as 2 μm. The light receiving surface of the p⁺ type semiconductor layer 32 was formed of a square shape of 20 μm×20 μm. A wavelength of light was decided as 905 nm.

In FIG. 13B, C1 is a light absorption efficiency in the region 80 of the photo detector 1005 which is provided with the optical path conversion portion 600. C2 is a light absorption efficiency in the region 80 of the photo detector 1005 which is provided with the optical path conversion portion 601. C3 indicates a light absorption efficiency of a photo detector in a case without the optical path conversion portion 600 or 601.

The length W of the optical path conversion portion 600 or 601 is 2.6 μm. The length W of the optical path conversion portion 600 or 601 is made not more than a definite value, the light absorption efficiency in the region 80 of the photo detector 1005 is improved, in the light of an infra-red region.

### Fifth Embodiment

FIG. 14A is a diagram showing a photo detector 1006, and FIG. 14B is a diagram showing a photo detector 1007.

In FIG. 14A, an optical path conversion portion (projection portion) 602 of the photo detector 1006 is a quadrangular pyramid having a bottom surface in an xy plane, and has a rectangular shape seen from the xy plane. The optical path conversion portion (projection portion) 602 is contained in the semiconductor layer 5. In addition, the optical path conversion portion (projection portion) 602 is not a part of the semiconductor layer 5, but may be a portion separate from the semiconductor layer 5.

A case in which the photo detector 1006 is seen from a yz plane will be considered.

An angle of a slope surface of a slope portion of the optical path conversion portion 602 to the p⁺ type semiconductor layer 32 serving as the light receiving surface is decided as α_{L}. If the angle α_{L} satisfies an expression (8) using a length L_{L} of the optical path conversion portion 602 in the horizontal direction, it is possible to confine a part of the light incident on the photo detector 1006 inside thereof.

$$\frac{1}{2} arcsin \frac{1}{{n}_{1}} \leq {α}_{L} \leq \frac{1}{2} arctan \frac{{L}_{L}}{D} \qquad ( 8 )$$

A case in which the photo detector 1006 is seen from an xz plane will be considered. An angle of a slope surface of a slope portion of the optical path conversion portion 602 to the p⁺ type semiconductor layer 32 serving as the light receiving surface is decided as α_{S}. A length of the optical path conversion portion 602 in the horizontal direction when the photo detector 1006 is seen from the xz plane is decided as L_{S}. The angle α_{S} of the photo detector 1006 has only to satisfy at least the expression (8) when the length L_{L} is larger than the length L_{S}. In addition, the angle α_{S} may also satisfy an expression (9) using the length L_{S} of the optical path conversion portion 602 in the horizontal direction.

In this manner, it is possible to confine at least a part of the light incident on the photo detector 1006 in the inside thereof.

$$\frac{1}{2} arcsin \frac{1}{{n}_{1}} \leq {α}_{S} \leq \frac{1}{2} arctan \frac{{L}_{S}}{D} \qquad ( 9 )$$

In FIG. 14B, an optical path conversion portion (projection portion) 605 of the photo detector 1007 is a cone having a bottom surface in an xz plane. The optical path conversion portion (projection portion) 605 is contained in the semiconductor layer 5. In addition, the optical path conversion portion (projection portion) 605 is not a part of the semiconductor layer 5, but may be a portion separate from the semiconductor layer 5.

An angle of a slope surface of a slope portion of the optical path conversion portion (projection portion) 605 to the p⁺ type semiconductor layer 32 serving as the light receiving surface is decided as α.

When the angle α of the slope surface of the slope portion of the optical path conversion portion 605 to the p⁺ type semiconductor layer 32 serving as the light receiving surface satisfies the expression (1), it is possible to confine the light incident on the photo detector 1007 inside the photo detector 1007 for at least one time.

### Sixth Embodiment

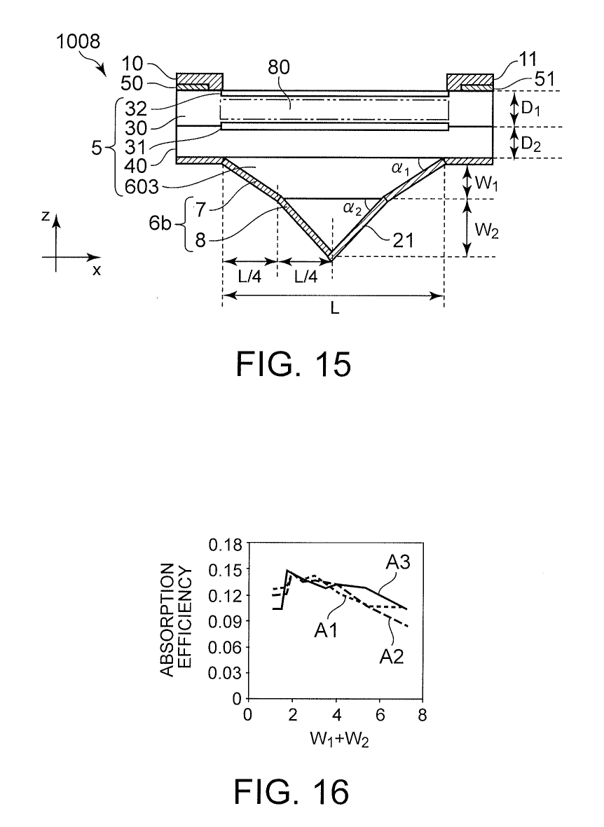

FIG. 15 is a diagram showing a photo detector 1008 which is provided with an optical path conversion portion (projection portion) 603.

The same symbols are given to the same portions as FIGS. 4A, 4B, and the description thereof will be omitted.

A slope portion 6b of the optical path conversion portion 603 is composed of a first slope portion 7 and a second slope portion following the first slope portion 7. An angle of the slope surface of the first slope portion 7 to the light receiving surface, and an angle of the slope surface of the second slope portion 8 to the light receiving surface are decided as α₁ and α₂, respectively.

In a direction from the light receiving surface toward the optical path conversion portion 603, a length of the first slope portion 7 and a length of the second slope portion 8 are respectively decided as W₁ and W₂. A length of the optical path conversion portion 603 in the horizontal direction is decided as L. In the horizontal direction, a length of the first slope portion 7, and a length of the second slope portion 8 are respectively decided as L/4, and L/4.

The optical path conversion portion (projection portion) 603 is contained in the semiconductor layer 5. In addition, the optical path conversion portion (projection portion) 603 is not a part of the semiconductor layer 5, but may be a portion separate from the semiconductor layer 5.

FIG. 16 is a diagram showing the relation between a light absorption efficiency of the photo detector 1008, and a sum of the length W₁ of the first slope portion 7 and the length W₂ of the second slope portion 8.

A1 is a case in which the angle α₁ of the slope surface of the first slope portion 7 to the light receiving surface is decided as 9 degrees, and the angle α₂ of the slope surface of the second slope portion 8 to the light receiving surface is decided as 1-45 degrees. A2 is a case in which the angle α₂ of the slope surface of the second slope portion 8 to the light receiving surface is decided as 9 degrees, and the angle α₁ of the slope surface of the first slope portion 7 to the light receiving surface is decided as 1-45 degrees. A3 is a case in which the angle α₁ and the angle α₂ are made the equal value.

Regardless of A1, A2, and A3, if the angle α₁ of the slope surface of the first slope portion 7 to the light receiving surface satisfies an expression (10), or the angle α₂ of the slope surface of the second slope portion 8 to the light receiving surface satisfies an expression (11), the light absorption efficiency of the photo detector 1008 is improved.

$$\begin{matrix}\frac{1}{2} arcsin \frac{1}{{n}_{1}} \leq {α}_{1} \leq \frac{1}{2} arctan \frac{L}{D} & ( 10 ) \\ \frac{1}{2} arcsin \frac{1}{{n}_{1}} \leq {α}_{2} \leq \frac{1}{2} arctan \frac{L}{D} & ( 11 )\end{matrix}$$

In addition, the light absorption efficiency of the photo detector 1008 is calculated assuming that the length L of the optical path conversion portion 603 is 25 μm, the length D₁ of the p type semiconductor layer 30 is 3.0 μm, the length D₂ of the n type semiconductor layer 40 is 3.0 μm.

### Seventh Embodiment

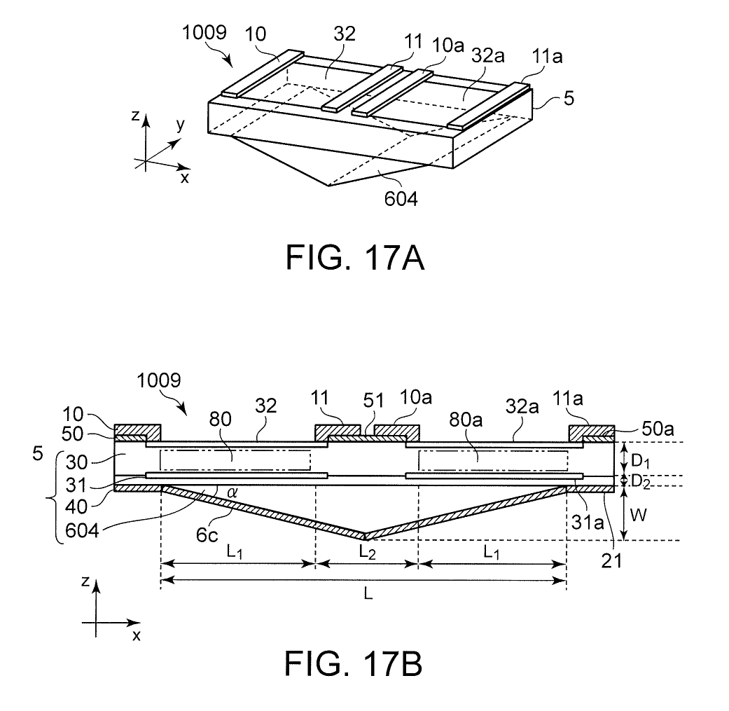

FIG. 17A is a diagram showing a photo detector 1009, and FIG. 17B is a diagram showing the photo detector 1009 seen from an xz plane.

The same symbols are given to the same portions as FIGS. 1A, 1B and FIGS. 4A, 4B, and the description thereof will be omitted.

In FIG. 17A, an optical path conversion portion (projection portion) 604 of the photo detector 1009 is a triangle pole having a bottom surface in a y direction in the same way as the optical path conversion portion 600 of the photo detector 1000 of FIGS. 1A, 1B. The photo detector 1009 has two p⁺ type semiconductor layers (light receiving surfaces) 32, 32a for the one optical path conversion portion 604. First electrodes 10a, 11a are provided at the same side as the p⁺ type semiconductor layer 32a. The first electrodes 10a, 11a are in contact with the p⁺ type semiconductor layer 32a. The optical path conversion portion 600 and the optical path conversion portion 604 have the same shape.

In the photo detector 1009 of FIG. 17B, an insulating layer is provided between the first electrode 11 and the p⁻ type semiconductor layer 30 and between the first electrode 10a and the p type semiconductor layer 30. An insulating layer 50a is provided between the first electrode 11a and the p⁻ type semiconductor layer 30. A p⁺ type semiconductor layer 31a is provided between the p⁻ type semiconductor layer 30 and the n type semiconductor layer 40.

The optical path conversion portion (projection portion) 604 is contained in the semiconductor layer 5. In addition, the optical path conversion portion (projection portion) 604 is not a part of the semiconductor layer 5, but may be a portion separate from the semiconductor layer 5.

There is the region 80 in which a depletion layer is to be formed between the p⁺ type semiconductor layer 32 and the p⁺ type semiconductor layer 31. There is a region 80a in which a depletion layer is to be formed between the p⁺ type semiconductor layer 32a and the p⁺ type semiconductor layer 31a.

The optical path conversion portion 604 has a slope portion 6c. An angle of a slope surface of the slope portion 6c to the p⁺ type semiconductor layers 32, 32a is a.

In a direction from the p⁺ type semiconductor layers 32, 32a side toward the optical path conversion portion 604, a length of the p⁻ type semiconductor layer 30 is decided as D₁, a length of the n type semiconductor layer 40 is decided as D₂. A sum of the length D₁ and the length D₂ is decided as D.

A length of the optical path conversion portion 604 in a direction from the p⁺ type semiconductor layers 32, 32a side toward the optical path conversion portion 604 is decided as W.

A length of the light receiving surface composed of the p⁺ type semiconductor layer 32 or 32a in the horizontal direction is L₁. A length between the light receiving surface composed of the p⁺ type semiconductor layer 32 and the light receiving surface composed of the p⁺ type semiconductor layer 32a is L₂. A length L of the optical path conversion portion 604 in the horizontal direction is 2 L₁+L₂.

When the angle α satisfies the expression (1) or the expression (3), it is possible to confine the light inside the photo detector 1009.

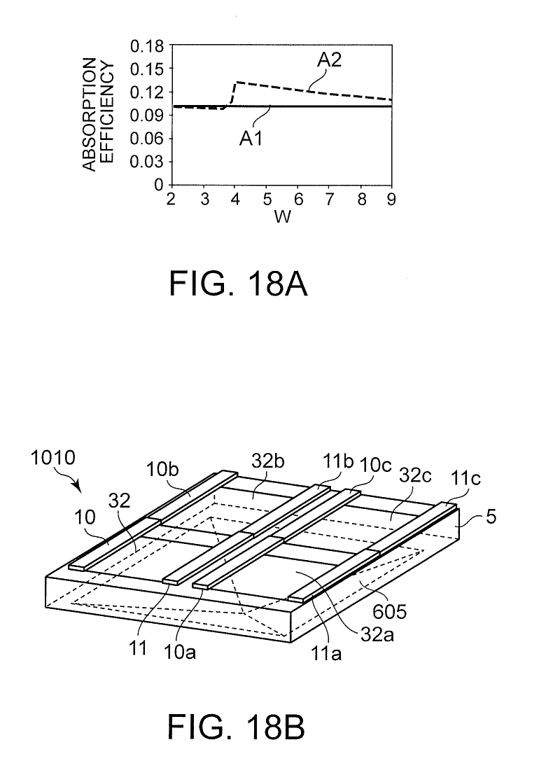

FIG. 18A is a diagram showing the relation between a light absorption efficiency in the regions 80, 80a and the length W of the optical path conversion portion 604, and FIG. 18B is a diagram showing a photo detector 1010.

A1 is a case in which the optical path conversion portion 604 is not provided. A2 is a case in which the optical path conversion portion 604 is provided.

In the case of A2, when the length W of the optical path conversion portion 604 becomes not less than at least 4.0 μm, the light absorption efficiency in the region 80, 80a is improved.

The angle α of the slope surface of the slope portion 6c of the optical path conversion portion 604 to the light receiving surface satisfies an expression (12).

$$\frac{1}{2} arcsin \frac{1}{{n}_{1}} \leq α \leq \frac{1}{2} arctan \frac{2 {L}_{1} + {L}_{2}}{D} \qquad ( 12 )$$

In addition, each of the p⁺ type semiconductor layers 32, 32a is a square shape. The length L₁ of one side of each of the p⁺ type semiconductor layers 32, 32a was decided as 25 μm. The length L₂ between the p⁺ type semiconductor layer 32 and the p⁺ type semiconductor layer 32a was decided as 6.0 μm. The length D₁ of the p⁻ type semiconductor layer 30 was decided as 3.0 μm, and the length D₂ of the n type semiconductor layer 40 was decided as 3.0 μm.

An optical path conversion portion (projection portion) 605 of the photo detector 1010 of FIG. 18B has the same shape as the optical path conversion portion 601 of the photo detector 1003. The optical path conversion portion (projection portion) 605 is contained in the semiconductor layer 5. In addition, the optical path conversion portion (projection portion) 605 is not a part of the semiconductor layer 5, but may be a portion separate from the semiconductor layer 5.

First electrodes 10b, llb are provided at respective one of both sides of a p⁺ type semiconductor layer 32b. First electrodes 10c, 11c are provided at respective one of both sides of a p⁺ type semiconductor layer 32c.

The photo detector 1010 has the four p⁺ type semiconductor layers 32, 32a, 32b, 32c for the one optical path conversion portion 605.

A photo detector is also able to have a plurality of the p⁺ type semiconductor layers for one optical path conversion portion (projection portion), in the same way as the photo detector 1010 and the photo detector 1009.

### Eighth Embodiment

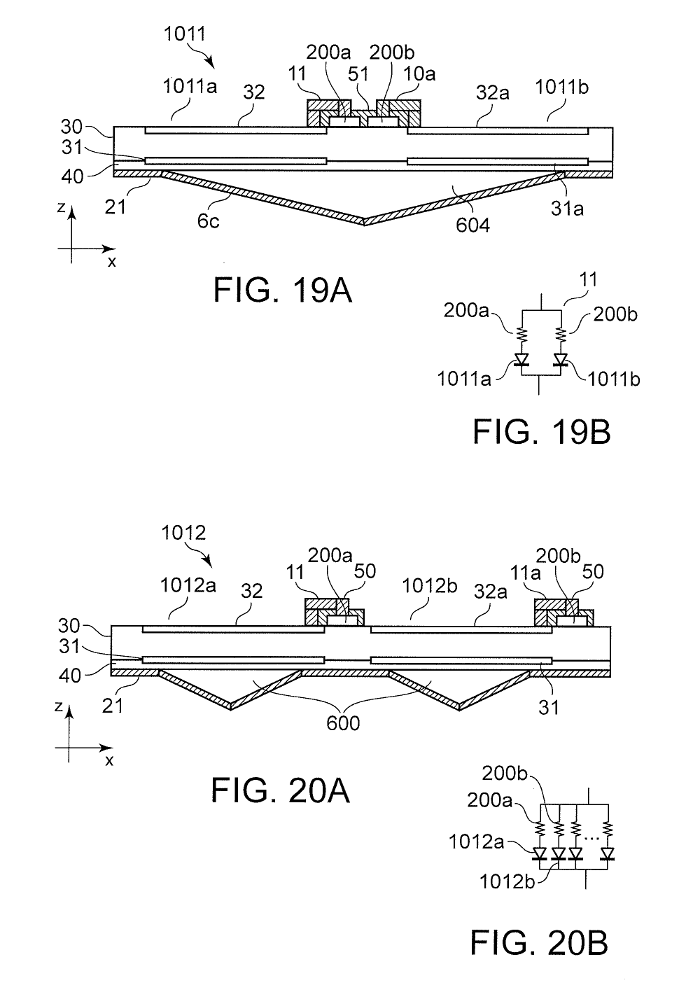

FIG. 19A is a diagram showing a photo detector 1011, and FIG. 19B is a circuit diagram of the photo detector 1011.

In FIG. 19A, the photo detector 1011 is further provided with quench resistors 200a, 200b in the photo detector 1009.

The quench resistors 200a and the quench resistor 200b are provided inside the insulating layer 51. The quench resistor 200a is connected to the p⁺ type semiconductor layer 32 via the first electrode 11. The quench resistor 200b is connected to the p⁺ type semiconductor layer 32a via the first electrode 10a.

A portion composed of the p⁺ type semiconductor layer 32, the p type semiconductor layer 30, the p⁺ type semiconductor layer 31, and the n type semiconductor layer 40 is decided as a photo detection portion 1011a. A portion composed of the p⁺ type semiconductor layer 32a, the p⁻ type semiconductor layer 30, the p⁺ type semiconductor layer 31a, and the n type semiconductor layer 40 is decided as a photo detection portion 1011b.

The quench resistor 200a adjusts a speed at the time of extracting current generated by avalanche amplification caused by the light incident from the p⁺ type semiconductor layer 32. The quench resistor 200b adjusts a speed at the time of extracting current generated by avalanche amplification caused by the light incident from the p⁺ type semiconductor layer 32a.

In FIG. 19B, the photo detection portion 1011a and the quench resistor 200a are connected in series with each other. The photo detection portion 1011b and the quench resistor 200b are connected in series with each other. The quench resistor 200a and the quench resistor 200b are connected in parallel with each other by wires

FIG. 20A is a diagram showing a photo detector 1012, and FIG. 20B is a circuit diagram of the photo detector 1012.

The same symbols are given to the same portions as FIGS. 1A, 1B, and the description thereof will be omitted.

The photo detector 1012 is composed by connecting a plurality of the photo detectors 1001.

The quench resistor 200a is connected to the p⁺ type semiconductor layer 32 via the first electrode 11. The quench resistor 200b is connected to the p⁺ type semiconductor layer 32a via the first electrode 11a.

A portion composed of the p⁺ type semiconductor layer 32, the p⁻ type semiconductor layer 30, the p⁺ type semiconductor layer 31, and the n type semiconductor layer 40 is decided as a photo detection portion 1012a. A portion composed of the p⁺ type semiconductor layer 32a, the p⁻ type semiconductor layer 30, the p⁺ type semiconductor layer 31a, and the n type semiconductor layer 40 is decided as a photo detection portion 1012b.

The quench resistor 200a adjusts a speed at the time of extracting current generated by avalanche amplification caused by the light incident from the p⁺ type semiconductor layer 32. The quench resistor 200b adjusts a speed at the time of extracting current generated by avalanche amplification caused by the light incident from the p⁺ type semiconductor layer 32a.

In FIG. 20B, the photo detection portion 1012a and the quench resistor 200a are connected in series with each other. The photo detection portion 1012b and the quench resistor 200b are connected in series with each other. The quench resistor 200a and the quench resistor 200b are connected in parallel with each other by wires.

In order to make the photo detection portions 1012, 1012a perform high speed response, an area of each of the p⁺ type semiconductor layer 32 and the p⁺ type semiconductor layer 32a serving as the light receiving surface is small. When the area of each of the p⁺ type semiconductor layer 32 and the p⁺ type semiconductor layer 32a serving as the light receiving surface is small, an amount of received light also becomes small. Accordingly, a detection strength of light of each of the photo detection portions 1012, 1012a becomes small.

In the photo detector 1012, the number of the photo detectors 1001 to be connected is increased, and thereby the detection signal of light of the photo detector 1012 is increased. The photo detector 1012 in which the photo detectors 1000 are connected has been shown, but in the photo detector 1012, a plurality of one kind of the photo detectors out of the photo detector 1003, the photo detector 1004, the photo detector 1005, the photo detector 1006, the photo detector 1007, the photo detector 1008, the photo detector 1009, and the photo detector 1010, except the photo detector 1001 may be connected. It is possible to connect, in the photo detector 1012, a plurality of kinds of the photo detectors out of the photo detector 1003, the photo detector 1004, the photo detector 1005, the photo detector 1006, the photo detector 1007, the photo detector 1008, the photo detector 1009, and the photo detector 1010, except the photo detector 1001.

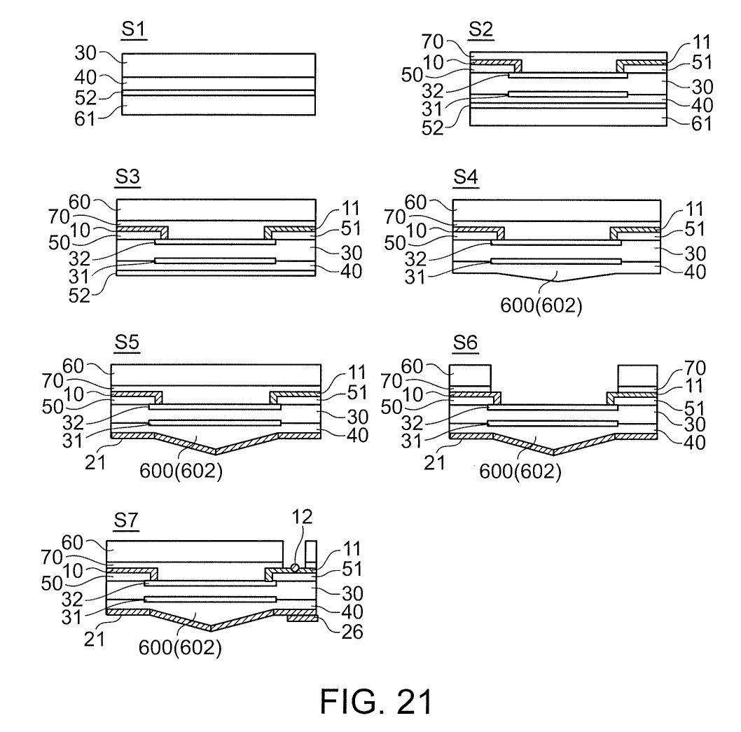

FIG. 21 is a diagram for describing a manufacturing method of the photo detector 1001 or the photo detector 1006.

A manufacturing method of the photo detector 1001 or the photo detector 1006 from an SOI (Silicon On Insulator) substrate is shown, but in addition to this, a substrate having a silicon layer (a p⁻ type, for example) which has been epitaxially grown on a silicon substrate 61 (an n type, for example) can be used, for example.

To begin with, an SOI substrate is prepared. The SOI substrate has a structure in which the silicon substrate 61, a BOX (buried oxide layer) 52, the active layer (n type semiconductor layer) 40 have been laminated in this order. The p⁻ type semiconductor layer 30 is formed on the n type semiconductor layer 40 by epitaxial growth (step S1).

Next, impurities (boron, for example) are implanted into the p type semiconductor layer 30 so that a part of the region thereof becomes the p⁺ type semiconductor layer 31. By this means, the ID⁺ type semiconductor layer 31 composing a photo detection element is formed on a portion of the active layer 40 of the SOI substrate. A first mask not shown is formed on the p⁻ type semiconductor layer 30, and p⁻ type impurities are implanted using this first mask, to form the p⁺ type semiconductor layer 32 serving as the photo detection region. After the first mask is removed, a second mask not shown is formed on the p⁺ type semiconductor layer 32. The insulating layer 50 and the insulating layer 51 are formed on the p type semiconductor layer 30 using this second mask. The first electrode 10 is formed so as to cover the insulating layer 50 and a peripheral portion of the p⁺ semiconductor layer 32. The first electrode 11 is formed so as to cover the insulating layer 51 and a peripheral portion of the p⁺ semiconductor layer 32. After the first electrodes 10, 11 are formed, the second mask is removed. A passivation layer 70 is formed so as to cover the first electrodes 10, 11, and a part of the p⁺ type semiconductor layer 32 (step 2).

The substrate 60 is adhered onto the passivation layer 70. The substrate 60 is made of glass, for example. The substrate 60 may be directly adhered onto the passivation layer 70, or the substrate 60 may be adhered onto the passivation layer 70 using an adhesive layer not shown. The silicon substrate 61 side is subjected to dry etching. In this dry etching, a reaction gas such as SF₆ can be used, for example. When a reaction gas having etch selectivity of the silicon substrate 61 and the BOX 52 is used in this dry etching, the BOX 52 can be used as an etching stop film. In addition, when the silicon substrate 61 is sufficiently thick, a polishing process such as back grinding and CMP (Chemical Mechanical Polishing), or wet etching may be used together. When wet etching is used, KOH or TMAH (Tetra-Methyl-Ammonium Hydroxide) can be used as etchant. The silicon substrate 61 is removed by means of this, and thereby the BOX 52 is exposed (step S3).

The exposed BOX 52 is removed by etching. As this etching, wet etching with hydrofluoric acid or the like can be used. Wet etching like this is used, and thereby etch selectivity of the BOX 52 and silicon can be sufficiently ensured, and the exposed BOX 52 can be selectively removed.

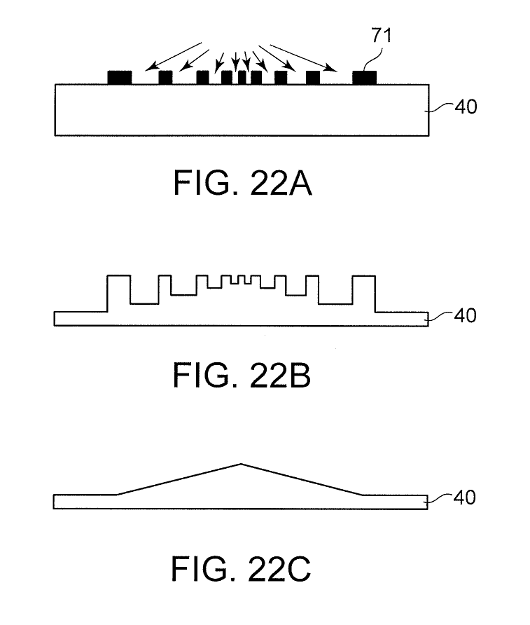

Here, a method of forming the optical path conversion portion 600 or 602 from the exposed n type semiconductor layer 40 will be described. As shown in FIG. 22A, masks 71 with different sizes are formed on the n type semiconductor layer 40. The n type semiconductor layer 40 is subjected to dry etching, using the masks 71. As shown in FIG. 22B, the n type semiconductor layer 40 is etched such that the larger an opening in a region is, the more deeply the n type semiconductor layer 40 in the region is etched in the film thickness direction. Next, after the mask 71 is removed, the regions where the masks 71 have been provided are etched by wet etching. By this wet etching, the optical path conversion portion 600 or 602 shown in FIG. 22C is formed (step S4).

Returning to FIG. 21, the reflective material 21 is formed on the exposed n type semiconductor layer 40 and the optical path conversion portion 600 or 602 (step S5).

In addition, an opening for the light detection region may be provided in the substrate 60 and the passivation layer 70, if necessary.

An opening is provided in a part of the substrate 60 on the first electrode 11. A first leading electrode 12 is formed on the first electrode 11 which has been exposed by the opening by wire bonding, for example. The first leading electrode may be formed by embedding an electrode made of metal material in the first electrode 11 at the opening. On a surface where the reflective portion 21 of the substrate 60 is to be formed, a second leading electrode 26 is formed so as to make contact with the reflective portion 21. The second leading electrode 26 may be formed on the n type semiconductor layer 40 by patterning, or by wire bonding. An insulating layer is provided between the n type semiconductor layer 40 and the second leading electrode 26, if necessary (step S7).

When a voltage serving as a reverse bias is applied between the first leading electrode 12 and the second leading electrode 26, the photodetector 1001 and the photo detector 1006 operate.

### Ninth Embodiment

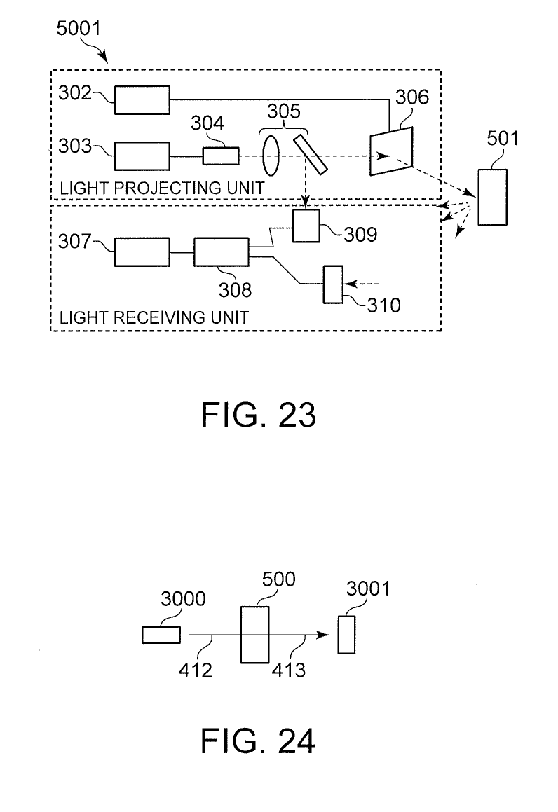

FIG. 23 is a diagram showing a LIDAR (Laser Imaging Detection and Ranging) device 5001.

The LIDAR device 5001 is provided with a light projecting unit and a light receiving unit. The light projecting unit is composed of a light oscillator 304, a drive circuit 303, an optical system 305, a scan mirror 306, and a scan mirror controller 302. The light receiving unit is composed of a reference light detector 309, a photo detector 310, a distance measuring circuit 308, and an image recognition system 307.

In the light projecting unit, the laser light oscillator 304 emits laser light. The drive circuit 303 drives the laser light oscillator 304. The optical system 305 extracts a part of the laser light as a reference light, and irradiates an object 501 with the other laser light via the mirror 306. The scan mirror controller 302 controls the scan mirror 306, to irradiate the object 501 with the laser light.

In the light receiving unit, the reference light detector 309 detects the reference light extracted by the optical system 305. The photo detector 310 receives reflected light from the object 501. The distance measuring circuit 308 measures a distance to the object 501, based on the reference light detected by the reference light detector 309 and the reflected light detected by the photo detector 310. The image recognition system 307 recognizes the object 501, based on the result measured by the distance measuring circuit 308.

The LIDAR device 5001 is a distance image sensing system employing a light flight time ranging method (Time of Flight) which measures a time required for laser light to reciprocate to a target, and converts the time into a distance. The LIDAR device 5001 is applied to an on-vehicle drive-assist system, remote sensing, and so on. If any of the photo detectors 1001, 1003, 1004, 1005, 1006, 1007, 1008, 1009, 1010, 1011, 1012 is used as the photo detector 310, the LIDAR device 5001 expresses good sensitivity, particularly in a near infra-red region. For this reason, it becomes possible to apply the LIDAR device 5001 to a light source in a human-invisible wavelength band. The LIDAR device 5001 can be applied for obstacle detection for vehicle, for example.

FIG. 24 is a diagram for describing a measuring system.

The measuring system includes at least a photo detector 3001 and a light source 3000. The light source 3000 of the measuring system emits a light 412 to an object 500 to become a measuring object. The photo detector 3001 detects a light 413 which has passed through the object 500 or has reflected or diffused from the object 500.

If any of the above-described photo detectors 1001, 1003, 1004-1012 is used as the photo detector 3001, for example, a measuring system having high sensitivity can be realized.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A photo detector, comprising:
a semiconductor layer having a projection portion provided at a side opposite to a light receiving surface side; and
a reflective material which covers a surface of the projection portion and reflects a light incident from the light receiving surface;
wherein:
the projection portion has a slope portion; and
an angle α of a slope surface of the slope portion to the light receiving surface satisfies
$$\frac{1}{2} arcsin \frac{1}{{n}_{1}} \leq α \leq \frac{1}{2} arctan \frac{L}{D}$$
using a refractive index n₁ of the projection portion of the semiconductor layer, a length D of the semiconductor layer in a direction from the light receiving surface toward the projection portion, and a length L of the projection portion in the horizontal direction.

2. The photo detector according to claim 1, wherein:
the angle α satisfies
$$\frac{1}{2} arcsin \frac{{n}_{2}}{{n}_{1}} \leq α , 2 W \leq - \frac{λ ln 0.5}{4 π k}$$
further using a length W of the projection portion in the direction from the light receiving surface toward the projection portion, a wavelength λ of the light, and an extinction coefficient k of the projection portion.

3. The photo detector according to claim 1, further comprising:
a substrate which transmits the light to the light receiving surface;
wherein the angle α satisfies any of
$$\begin{matrix}\frac{1}{2} arcsin \frac{{n}_{2}}{{n}_{1}} \leq α \leq \frac{1}{2} arctan \frac{L}{D} \\ and \\ \frac{1}{2} arcsin \frac{{n}_{2}}{{n}_{1}} \leq α , 2 W \leq - \frac{λ ln 0.5}{4 π k}\end{matrix}$$
further using a refractive index n₂ of the substrate.

4. The photo detector according to claim 1, wherein:
the semiconductor layer includes a p⁻ type semiconductor layer and an n type semiconductor layer in this order in the direction from the light receiving surface toward the projection portion.

5. The photo detector according to claim 4, wherein:
the p⁻ type semiconductor layer includes a p⁺ type semiconductor layer, a p⁻ type semiconductor layer, a p⁺ type semiconductor layer in this order in the direction from the light receiving surface toward the projection portion.

6. The photo detector according to claim 1, wherein:
the semiconductor layer includes an n type semiconductor layer and a p⁻ type semiconductor layer in this order in the direction from the light receiving surface toward the projection portion.

7. The photo detector according to claim 6, wherein:
the n type semiconductor layer includes an n⁺ type semiconductor layer, an n⁻ type semiconductor layer, an n⁺ type semiconductor layer in this order in the direction from the light receiving surface toward the projection portion.

8. The photo detector according to claim 1, wherein:
the slope portion of the projection portion of the semiconductor layer comprises a first slope portion and a second slope portion following the first slope portion; and
when in the direction from the light receiving surface toward the projection portion, a length of the first slope portion is W₁, and a length of the second slope portion is W₂, and
when to the light receiving surface, an angle of a slope surface of the first slope portion is α₁, and an angle of a slope surface of the second slope portion is α₂,
the angle α₁ satisfies
$$\frac{1}{2} arcsin \frac{1}{{n}_{1}} \leq {α}_{1} \leq \frac{1}{2} arctan \frac{L}{D}$$
and the angle α₂ satisfies
$$\frac{1}{2} arcsin \frac{1}{{n}_{1}} \leq {α}_{2} \leq \frac{1}{2} arctan \frac{L}{D}$$

9. The photo detector according to claim 1, wherein:
the light receiving surface has a quadrangular shape, and a length of a side is not less than 20 μm and not more than 30 μm.

10. The photo detector according to claim 1, wherein:
the length D of the semiconductor layer is not less than 1 μm and not more than 10 μm.

11. The photo detector according to claim 1, wherein:
an electric conductivity of the reflective material is higher than an electric conductivity of the projection portion.

12. The photo detector according to claim 1, wherein:
a plurality of the light receiving surfaces are provided for the one projection portion.

13. The photo detector according to claim 1, wherein:
a wavelength of the light is not less than 750 nm and not more than 1000 nm.

14. The photo detector according to claim 1, wherein:
the semiconductor layer includes Si.

15. A LIDAR device, comprising:
a light source to irradiate an object with light;
the photo detector according to claim 1 which detects the light reflected by the object; and
a measuring unit to measure a distance between the object and the photo detector.
